(19) United States
(12) Patent Application Publication
(10) Pub. No.: US 2016/0099202 A1
(43) Pub. Date: Apr. 7, 2016

(54) SEMICONDUCTOR PACKAGING STRUCTURE

(71) Applicant: Powertech Technology Inc., Hsinchu County (TW)

(72) Inventor: Ming-Hung Lin, Hsinchu County (TW)

(21) Appl. No.: 14/548,307

(22) Filed: Nov. 20, 2014

(30) Foreign Application Priority Data
Oct. 3, 2014 (TW) 103134553

(51) Int. Cl. H01L 23/498; H01L 23/48; H01L 23/00

(52) U.S. Cl. CPC H01L 23/49838; H01L 23/49822; H01L 23/49827; H01L 24/32; H01L 23/481; H01L 2224/32225

(57) ABSTRACT

A semiconductor packaging structure including a circuit board, a chip, and a paste is provided. The circuit board includes a base layer, a first circuit layer, and a second circuit layer. The base layer has a first surface, a second surface opposite to the first surface, and a recess located on the first surface. The first circuit layer is located on the first surface. The second circuit layer is located on the second surface. The chip is disposed on the first surface and is electrically connected to first circuit layer, where the recess is located on at least one side of the chip. The paste is filled between the chip and the first surface and filled in the recess, where the paste covers a side surface of the chip.

### CROSS-REFERENCE TO RELATED APPLICATION

This application claims the priority benefit of Taiwan application serial no. 103134553, filed on Oct. 3, 2014. The entirety of the above-mentioned patent application is hereby incorporated by reference herein and made a part of this specification.

### BACKGROUND

1. Technical Field

The invention relates to a packaging structure, and particularly relates to a semiconductor packaging structure.

2. Related Art

To use a three-dimensional (3D) integrated circuit (IC) integration technique to provide a high density packaging technique and achieve effects of high efficiency and low power consumption is one of the most promising solutions for future large chip operation. Especially, in data transmission between a central processing unit (CPU), a cache memory, a flash memory in memory card application and a controller, the efficiency advantage brought by a short distance internal bonding path based on through silicon via (TSV) can be more prominent.

Therefore, in the field of portable electronic products that emphasize multi-function and small size, regarding the stacking structure of a solid state disk (SSD) and a dynamic random access memory (DRAM), etc., besides that the high speed performance emphasized by the application is strengthened, it also avails decreasing an IC power consumption. Under a same input/output (I/O) number, power consumption required for driving is decreased, and demands on capacity, performance and I/O increase are synchronously satisfied. Moreover, miniaturization of the 3D IC is a primary factor for marketing, and main techniques of the 3D IC integration technique include TSV, micro bump contact fabrication, wafer thinning, alignment, bonding and a dispensing process.

In the current 3D IC integration technique, the stacking technique is mainly developed towards a trend of a 10 μm level pitch and a thin chip with a thickness below 50 μm, though in the dispensing process, a paste filled between an active surface of the chip and a carrier is liable to overflow to a back surface of the chip along a side surface of the chip under pressure.

### SUMMARY

The invention is directed to a semiconductor packaging structure, which is capable of effectively prevent occurrence of a paste overflow phenomenon, so as to maintain a good production yield.

The invention provides a semiconductor packaging structure including a circuit substrate, a chip, and a paste. The circuit substrate includes a base layer, a first circuit layer and a second circuit layer. The base layer has a first surface, a second surface opposite to the first surface, and a recess located on the first surface. The first circuit layer is located on the first surface. The second circuit layer is located on the second surface. The chip is disposed on the first surface and is electrically connected to the first circuit layer, where the recess is located on at least one side of the chip. The paste is filled between the chip and the first surface and filled in the recess, where the paste covers a side surface of the chip.

In an embodiment of the invention, the circuit substrate further includes a plurality of conductive vias. The conductive vias penetrate through the base layer and are electrically connected to the first circuit layer and the second circuit layer.

In an embodiment of the invention, the recess surrounds the chip.

In an embodiment of the invention, the chip has an active surface and a back surface opposite to the active surface. The side surface is connected to the active surface and the back surface.

In an embodiment of the invention, the paste is filled between the active surface and the first surface, and an upper edge of the paste covering the side surface is lower than the back surface.

In an embodiment of the invention, the paste is filled between the active surface and the first surface, and an upper edge of the paste covering the side surface is aligned to the back surface.

In an embodiment of the invention, the chip includes a plurality of first pads located on the active surface, a plurality of second pads located on the back surface and a plurality of conductive vias penetrating through the active surface and the back surface. Each of the first pads is electrically connected to the corresponding second pad through the corresponding conductive via.

In an embodiment of the invention, a sum of a thickness of the chip, a space between the active surface and the first surface, and a depth of the recess is greater than or equal to 100 μm.

In an embodiment of the invention, a bottom surface of the recess is parallel to the first surface.

In an embodiment of the invention, a bottom surface of the recess is inclined to the first surface.

In an embodiment of the invention, the bottom surface of the recess is connected to the first surface.

In an embodiment of the invention, a width of the recess is greater than or equal to 150 μm.

According to the above descriptions, in the semiconductor packaging structure of the invention, the recess is configured on the circuit substrate, where the recess is, for example, located on at least one side of the chip, or surrounds the chip.

Since the recess is used as a reserved space for accommodating the paste, when the paste filled between the chip and the circuit substrate is squeezed under an external force, the paste can flow into the recess without climbing to the back surface of the chip along the side surface of the chip. In this way, occurrence of a paste overflow phenomenon is effectively prevented, so as to maintain a good production yield.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor packaging structure according to an embodiment of the invention.

FIG. 2 is a top view of the semiconductor packaging structure of FIG. 1.

FIG. 3 is a cross-sectional view of a semiconductor packaging structure according to another embodiment of the invention.

FIG. 4 is a cross-sectional view of a semiconductor packaging structure according to still another embodiment of the invention.

FIG. 5 is a cross-sectional view of a semiconductor packaging structure according to yet another embodiment of the invention.

### DETAILED DESCRIPTION OF DISCLOSED EMBODIMENTS

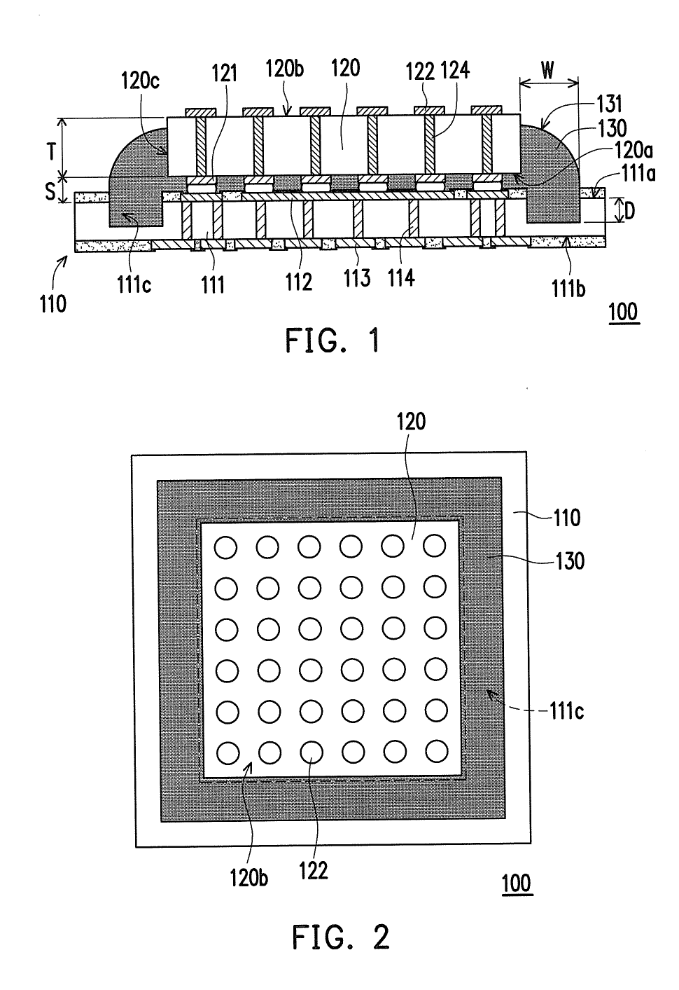

FIG. 1 is a cross-sectional view of a semiconductor packaging structure according to an embodiment of the invention. FIG. 2 is a top view of the semiconductor packaging structure of FIG. 1. Referring to FIG. 1 and FIG. 2, in the present embodiment, the semiconductor packaging structure 100 includes a circuit substrate 110, a chip 120, and a paste 130. The circuit substrate 110 is, for example, a BT stacking substrate, a FR-4 substrate, a FR-5 substrate, a ceramic substrate, or a polyimide substrate, etc. Generally, the circuit substrate 110 may include a base layer 111, a first circuit layer 112 and a second circuit layer 113, wherein the base layer 111 has a first surface 111a, a second surface 111b opposite to the first surface 111a, and a recess 111c located on the first surface 111a. The recess 111c is, for example, formed by removing a part of material of the base layer 111 through a laser etching manner.

The first circuit layer 112 is located on the first surface 111a, and the second circuit layer 113 is located on the second surface 111b. The chip 120 is disposed on the first surface 111a and is electrically connected to the first circuit layer 112, wherein the recess 111c is located on at least one side of the chip 120. Here, a situation that the recess 111c surrounds the chip 120 is taken as an example for description, though the invention is not limited thereto. On the other hand, the circuit substrate 110 further includes a plurality of conductive vias 114. The conductive vias 114 penetrate through the base layer 111 and are electrically connected to the first circuit layer 112 and the second circuit layer 113.

Generally, the chip 120 has an active surface 120a, a back surface 120b opposite to the active surface 120a, and a side surface 120c connected to the active surface 120a and the back surface 120b. The chip 120 is, for example, a through silicon via (TSV) chip, which includes a plurality of first pads 121 located on the active surface 120a, a plurality of second pads 122 located on the back surface 120b and a plurality of conductive vias 124 penetrating through the active surface 120a and the back surface 120b, where each of the first pads 121 is electrically connected to the corresponding second pad 122 through the corresponding conductive via 124, and the first pads 121 of the chip 120 are electrically connected to the first circuit layer 112 through a flip chip bonding technique.

After the electrical bonding step between the first pads 121 of the chip 120 and the first circuit layer 112 of the circuit substrate 110 is completed, a dispensing head (not shown) is generally used to perform a dispensing process along the side surface 120c of the chip 120. Now, the paste 130 (for example, a non-conductive paste) provided by the dispensing head (not shown) is first filled between the active surface 120a of the chip 120 and the first surface 111a of the base layer 111, and after the space between the active surface 120a of the chip 120 and the first surface 111a of the base layer 111 is filled up, the paste 130 may flow to other regions outside the first surface 111a of the base layer 111. Further, since the first surface 111a of the base layer 111 is configured with the recess 111c surrounding the chip 120, the paste 130 may further fill into the recess 111c, and climbs up along the side surface 120c of the chip 120. After the dispensing is stopped, the paste 130 does not completely fill in the recess 111c. In order to stably bond the chip 120 and the circuit substrate 110 through the paste 130, an external force is generally exerted to press the chip 120 and the circuit substrate 110 against each other.

During the process of pressing the chip 120 and the circuit substrate 110 against each other, a part of the paste 130 filled between the active surface 120a of the chip 120 and the first surface 111a of the base layer 111 may overflow into the recess 111c, and when an amount of the paste 130 overflowed from the space between the active surface 120a of the chip 120 and the first surface 111a of the base layer 111 is relatively large, the recess 111c is filled full by the paste 130, and the paste 130 covers the side surface 120c of the chip 120. In detail, the recess 111c can serve as a reserved space for accommodating the paste 130, and when the paste 130 filled between the chip 120 and the circuit substrate 119 is squeezed by an external force, the paste 130 can flow into the recess 111c without climbing to the back surface 120b of the chip 120 along the side surface 120c of the chip 120. In this way, occurrence of a paste overflow phenomenon is effectively prevented, so as to maintain a good production yield. Generally, an upper edge 131 of the paste 130 covering the side surface 120c of the chip 120 is slightly lower than the back surface 120c of the chip 120, or is aligned to the back surface 120c of the chip 120, which is not limited by the invention.

As shown in FIG. 1, in the present embodiment, a bottom surface of the recess 111c is, for example, parallel to the first surface 111a of the base layer 111, where a sum of a thickness T of the chip 120, a space S between the active surface 120a of the chip 120 and the first surface 111a of the base layer 111, and a depth D of the recess 111c is greater than or equal to 100 μm, and the chip 120 is, for example, a thin chip under a thickness level of 50 μm. On the other hand, a width of the recess 111c is, for example, greater than or equal to 150 μm, so as to provide an enough reserved space to accommodate the paste 130.

Embodiments are provided below for further description. It should be noticed that reference numbers of the components and a part of contents of the aforementioned embodiment are also used in the following embodiment, wherein the same reference numbers denote the same or like components, and descriptions of the same technical contents are omitted. The aforementioned embodiment can be referred for descriptions of the omitted parts, and detailed descriptions thereof are not repeated in the following embodiment.

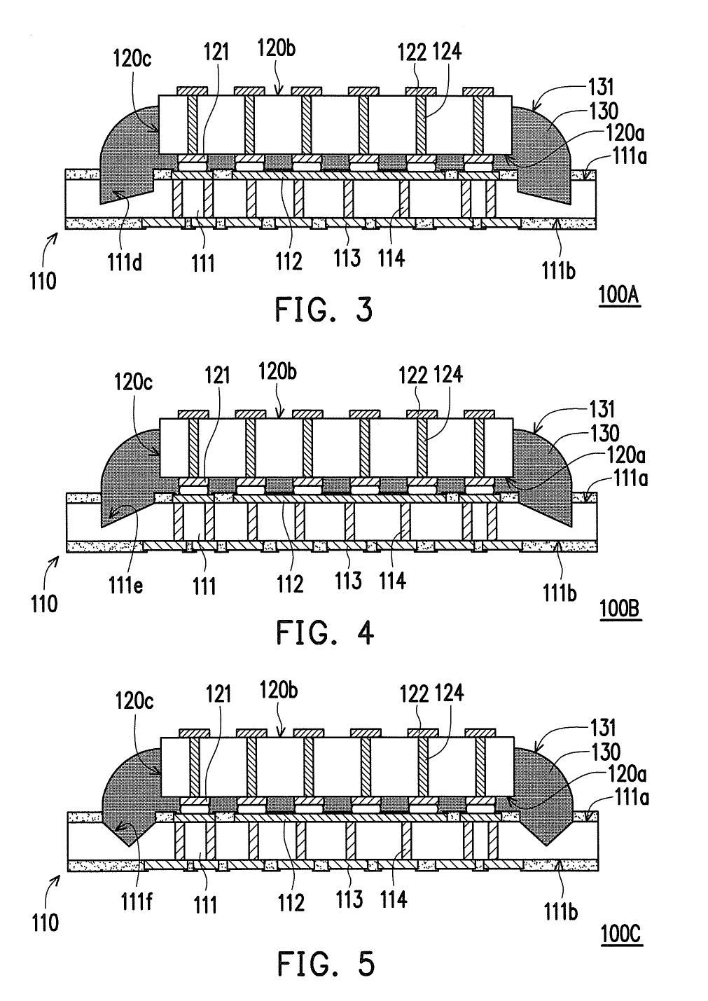

FIG. 3 is a cross-sectional view of a semiconductor packaging structure according to another embodiment of the invention. Referring to FIG. 3, the semiconductor packaging structure 100A is substantially similar to the semiconductor packaging structure 100, and a main difference there between is that the bottom surface of the recess 111d is inclined to the first surface 111a of the base layer 111. Namely, a profile of a cross section of the recess 111d is approximately a trapezoid, and a side of the bottom surface of the recess 111d that is close to the chip 120 is, for example, higher than another side of the bottom surface of the recess 111d that is away from the chip 120, though the invention is not limited thereto. In other embodiments, the side of the bottom surface of the recess 111d that is close to the chip 120 can be lower than the other side of the bottom surface of the recess 111d that is away from the chip 120.

FIG. 4 is a cross-sectional view of a semiconductor packaging structure according to still another embodiment of the invention. Referring to FIG. 4, the semiconductor packaging structure 100B is substantially similar to the semiconductor packaging structure 100, and a main difference there between is that the bottom surface of the recess 111e is inclined to the first surface 111a of the base layer 111 and is connected to the first surface 111a of the base layer 111. Namely, a profile of a cross section of the recess 111e is approximately a right-angled triangle, where the bottom surface of the recess 111e is, for example, connected to the first surface 111a of the base layer 111 at a place close to the chip 120, though the invention is not limited thereto.

In other embodiments, the bottom surface of the recess 111e can also be connected to the first surface 111a of the base layer 111 at a place away from the chip 120.

FIG. 5 is a cross-sectional view of a semiconductor packaging structure according to yet another embodiment of the invention. Referring to FIG. 5, the semiconductor packaging structure 100C is substantially similar to the semiconductor packaging structure 100, and a main difference there between is that the bottom surface of the recess 111f is inclined to the first surface 111a of the base layer 111, where two sides of the bottom surface of the recess 111f are all connected to the first surface 111a of the base layer 111. Namely, a profile of a cross section of the recess 111f is approximately a triangle, for example, an isosceles triangle or an equilateral triangle.

In summary, in the semiconductor packaging structure of the invention, the recess is configured on the circuit substrate, where the recess is, for example, located on at least one side of the chip, or surrounds the chip. Since the recess is used as a reserved space for accommodating the paste, when the paste filled between the chip and the circuit substrate is squeezed under an external force, the paste can flow into the recess without climbing to the back surface of the chip along the side surface of the chip. In this way, occurrence of a paste overflow phenomenon is effectively prevented, so as to maintain a good production yield.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A semiconductor packaging structure, comprising:
a circuit substrate, comprising:
a base layer, having a first surface, a second surface opposite to the first surface, and a recess located on the first surface;
a first circuit layer, located on the first surface; and
a second circuit layer, located on the second surface;
a chip, disposed on the first surface, and electrically connected to the first circuit layer, wherein the recess is located on at least one side of the chip; and
a paste, filled between the chip and the first surface and filled in the recess, wherein the paste covers a side surface of the chip.

2. The semiconductor packaging structure as claimed in claim 1, wherein the circuit substrate further comprises a plurality of conductive vias penetrating through the base layer and electrically connecting to the first circuit layer and the second circuit layer.

3. The semiconductor packaging structure as claimed in claim 1, wherein the recess surrounds the chip.

4. The semiconductor packaging structure as claimed in claim 1, wherein the chip has an active surface and a back surface opposite to the active surface, and the side surface is connected to the active surface and the back surface.

5. The semiconductor packaging structure as claimed in claim 4, wherein the paste is filled between the active surface and the first surface, and an upper edge of the paste covering the side surface is lower than the back surface.

6. The semiconductor packaging structure as claimed in claim 4, wherein the paste is filled between the active surface and the first surface, and an upper edge of the paste covering the side surface is aligned to the back surface.

7. The semiconductor packaging structure as claimed in claim 4, wherein the chip comprises a plurality of first pads located on the active surface, a plurality of second pads located on the back surface and a plurality of conductive vias penetrating through the active surface and the back surface, and each of the first pads is electrically connected to the corresponding second pad through the corresponding conductive via.

8. The semiconductor packaging structure as claimed in claim 4, wherein a sum of a thickness of the chip, a space between the active surface and the first surface, and a depth of the recess is greater than or equal to 100 μm.

9. The semiconductor packaging structure as claimed in claim 1, wherein a bottom surface of the recess is parallel to the first surface.

10. The semiconductor packaging structure as claimed in claim 1, wherein a bottom surface of the recess is inclined to the first surface.

11. The semiconductor packaging structure as claimed in claim 10, wherein the bottom surface of the recess is connected to the first surface.

12. The semiconductor packaging structure as claimed in claim 1, wherein a width of the recess is greater than or equal to 150 μm.
